(19) United States
(12) Patent Application Publication
(10) Pub. No.: US 2012/0243331 A1
(43) Pub. Date: Sep. 27, 2012

(54) SEMICONDUCTOR MEMORY DEVICE

(76) Inventors: Tomofumi Fujimura, Fujisawa-shi (JP); Yuya Suzuki, Kamakura-shi (JP)

(21) Appl. No.: 13/428,497

(22) Filed: Mar. 23, 2012

(30) Foreign Application Priority Data
Mar. 24, 2011 (JP) 2011-066182

(51) Int. Cl. G11C 16/10

(52) U.S. Cl. 365/185.22

(57) ABSTRACT

According to one embodiment, a semiconductor memory device includes a cell array, a voltage generator, and a controller. The memory cells are formed along rows and columns. The voltage generator generates a write voltage and a verify voltage. The voltage generator transfers a first voltage to the memory cell having a threshold voltage lower than the verify voltage. The voltage generator transfers a second voltage lower than the first voltage. The controller causes the voltage generator to transfer the verify voltage to the memory cell and to terminate a write operation. The controller performs the writing at least twice.

### CROSS-REFERENCE TO RELATED APPLICATIONS

This application is based upon and claims the benefit of priority from prior Japanese Patent Application No. 2011-066182, filed Mar. 24, 2011, the entire contents of which are incorporated herein by reference.

### FIELD

Embodiments described herein relate generally to a semiconductor memory device capable of narrowing a distribution of thresholds of memory cells.

### BACKGROUND

There is a method for enhancing an accuracy of controlling a threshold by increasing a write voltage at a constant rate when data is written in a NAND flash memory.

However, a distribution of thresholds tends to be wider than expected due to a difference between individual memory cells, an initial state or an influence by neighboring cells.

Thus, there is, as a method for solving the problem, a method for narrowing a distribution of thresholds by gradually decreasing a write pulse. However, the writing by the method takes a time.

### BRIEF DESCRIPTION OF THE DRAWINGS

FIG. 1 shows an entire structure of a NAND flash memory according to a first embodiment;

FIG. 2 shows a distribution of thresholds of memory cells according to the first embodiment;

FIG. 3 is a conceptual diagram of a voltage generator according to the first embodiment;

FIG. 4 is a flowchart showing a write operation and a verify operation according to the first embodiment;

FIG. 5 is a conceptual diagram showing the write operation and the verify operation according to the first embodiment;

FIGS. 6A and 6B, and FIGS. 7A and 7B are each a time chart showing the write operation and a verify voltage according to the first embodiment; and

FIG. 8 is a time chart showing a write operation and a verify voltage according to a second embodiment.

### DETAILED DESCRIPTION

Embodiments will be described below with reference to the drawings. In the description, like reference numerals are denoted to like constituents throughout the drawings.

In general, according to one embodiment, a semiconductor memory device includes a memory cell array, a voltage generator, and a controller.

Memory cells capable of holding two- or more-level data. The memory cells are formed along rows and columns in a memory cell array. The voltage generator generates a write voltage and a verify voltage depending on the number of times of writing. The voltage generator transfers a first voltage as the write voltage to the memory cell having a threshold voltage lower than the verify voltage depending on the number of times of writing. The voltage generator transfers a second voltage lower than the first voltage as the write voltage to the memory cell having a threshold voltage higher than the verify voltage. The controller causes the voltage generator to transfer the verify voltage to the memory cell and to terminate a write operation when the number of memory cells having a threshold exceeding a predetermined voltage reaches half the total number. The controller performs the writing at least twice.

### First Embodiment

A semiconductor memory device according to the present embodiment conducts verification at a median value in a distribution of thresholds of memory cells per writing, and applies a higher write voltage to memory cells having a threshold voltage lower than the verify voltage than to memory cells having a threshold voltage higher than the verify voltage. Thereby, the distribution of thresholds of the memory cells is narrowed whenever the write operation is repeated. Further, when the distribution of thresholds of more than half the memory cells reaches a predetermined voltage, it is determined that the memory cells at a lower potential in the distribution of thresholds of the memory cells are within a relievable range, and the data write operation is terminated. Thereby, a data write processing speed can be enhanced.

<Entire Structure>

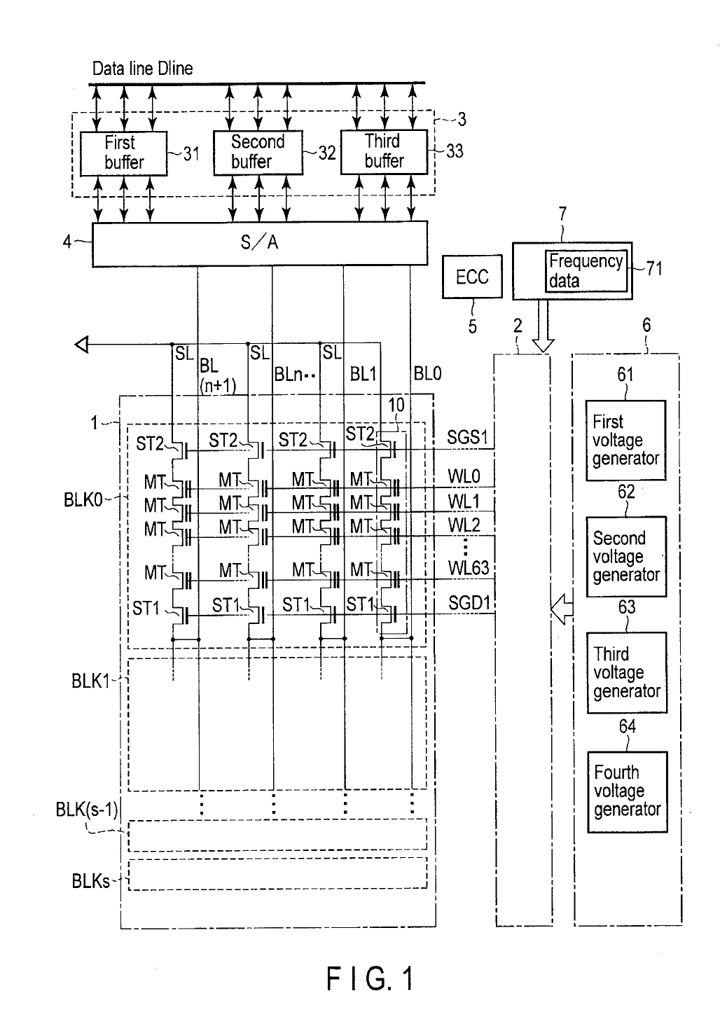

The semiconductor memory device according to the first embodiment will be described below with reference to FIG. 1. FIG. 1 is an entire structure diagram showing an exemplary semiconductor memory device to which a NAND flash memory is applied. As shown in FIG. 1, the NAND flash memory comprises a memory cell array 1, a row decoder 2, a buffer 3, a sense amplifier 4, an ECC (Error check and correction) circuit 5, a voltage generator 6, and a controller 7.

<Memory Cell Array 1>

The memory cell array 1 comprises blocks BLK0 to BLKs (s is a natural number) each including a plurality of nonvolatile memory cell transistors MT (memory cells MC). Each of the blocks BLK0 to BLKs comprises a plurality of NAND strings 10 in which the nonvolatile memory cells MC are connected in series. Each NAND string 10 includes 64 memory cells MC and select transistors ST1, ST2, for example.

The memory cell MC can hold two- or more-level data. The present embodiment will be described assuming that items of two-level data at different levels are held, but the data may be four-level or eight-level and is not limited thereto.

A structure of the memory cell MC is of a FG type including a float gate (conductive layer) formed on a p-type semiconductor substrate via a gate insulative film and a control gate formed on the float gate via an inter-gate insulative film. The memory cell MC may be of a MONOS type. The MONOS type is a structure having a charge accumulation layer (such as insulative film) formed on a semiconductor substrate via a gate insulative film, an insulative film (which will be called block layer below) formed on the charge accumulation layer and having a higher dielectric than the charge accumulation layer, and a control gate formed on the block layer.

The control gate of the memory cell MC functions as a word line, a drain is electrically connected to a bit line, and a source is electrically connected to a source line. The memory cell MC is an n-channel MOS transistor. The number of memory cells MC is not limited to 64 and may be 128 or 256, and the number is not limited thereto.

The adjacent memory cells share the source and the drain. Current paths are connected in series between the select transistors ST1 and ST2. A drain region at one end of the memory cell MC connected in series is connected to a source region of the select transistor ST1, and a source region at the other end is connected to a drain region of the select transistor ST2.

The control gates of the memory cells MC in the same row are commonly connected to any of the word lines WL0 to WL63, and gate electrodes of the select transistors ST1, ST2 of the memory cells MC in the same row are commonly connected to select gate lines SGD1, SGS1, respectively. For a simplified explanation, when the word lines WL0 to WL63 are not discriminated, they will be simply called word line WL below. The drains of the select transistors ST1 in the same column in the memory cell array 1 are commonly connected to any of bit lines BL0 to BLn. When the bit lines BL0 to BLn are not discriminated, they will be simply called bit line BL below (n: a natural number). The sources of the select transistors ST2 are commonly connected to a source line SL.

Data is collectively written in the memory cells MC connected to the same word line WL, which unit is called page. Further, the data is collectively erased from the memory cells MC in units of BLK.

<Distribution of Thresholds of Memory Cell Transistors MT>

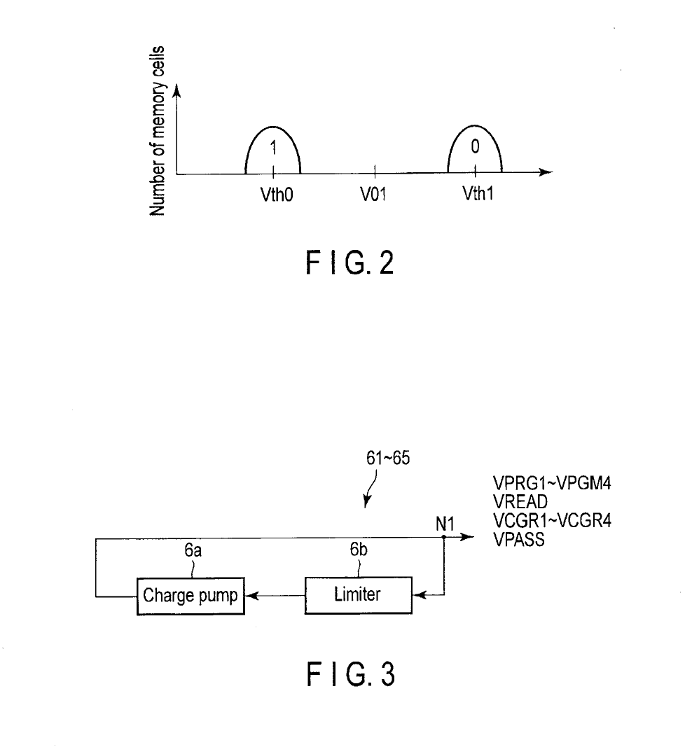

A distribution of thresholds of the memory cells MC will be described below with reference to FIG. 2. FIG. 2 is a graph with the horizontal axis of the distribution of thresholds and the vertical axis of the number of memory cells MC.

As illustrated, each memory cell MC can hold 2-level data (1-bit data), for example. In other words, the memory cell MC can two kinds of data “1” and “0” in ascending order of threshold voltage Vth.

A threshold voltage Vth0 of the “1” data in the memory cell MC is of Vth0<V01. A threshold voltage Vth1 of the “0” data is of V01<Vth1. In this way, the memory cell MC can hold 1-bit data of the “0” data and the “1” data depending on the threshold. The threshold voltage varies by injecting charges into the charge accumulation layer. It may be assumed that the memory cell MC can hold four- or more-level data.

<Row Decoder 2>

Turning to FIG. 1, the row decoder 2 will be described. The row decoder 2 decodes a block address given from the controller 7 and selects a block BLK based on the decode result during the data write operation and read operation. Thereby, the row decoder 2 selects a row direction of the memory cell array 1 corresponding to the selected block BLK. That is, the row decoder 2 applies a voltage given from the driver circuit 3 to the select gate lines SGD1, SGS1 and the word lines WL0 to WL63 based on a control signal given from the controller 7.

<Buffer 3>

The buffer 3 holds write data transferred from an external device (host) (not shown) via a data line Dline. Further, it temporarily holds the held data read by the sense amplifier 4 from the memory cells MC, and transfers it to the external device via the data line Dline. Further, it holds data as to whether the threshold voltage of the memory cells MC after the write operation is higher (second group described later) or lower (first group described later) than the verify voltage according to the number of times of writing.

The buffer 3 comprises a first buffer to a third buffer. For example, it is assumed that the first buffer 31 can hold write data and read data. It is assumed that the second buffer 32 and the third buffer 33 can hold the data as to whether the threshold voltage of the memory cells MC after the write operation is higher or lower than the verify voltage, that is the data as to whether it is in the first group or the second group. Specifically, the second buffer 32 uses a verify level (described in the first embodiment) for the distribution of thresholds of the memory cells MC to hold the data as to whether the threshold voltage of the memory cells MC is higher than the verify level, and the third buffer 33 uses two verify levels (described in the second embodiment) for the distribution of thresholds of the memory cells MC to hold the data as to where the threshold voltage of the memory cells MC is positioned relative to the verify levels.

<Sense Amplifier 4>

The sense amplifier 4 will be described below. The sense amplifier 4 senses and amplifies the data read from the bit line BL (the bit line BL to be read) connected to the memory cell MC to be read during the data reading. That is, the sense amplifier 4 precharges the bit line BL to be read at a predetermined voltage (such as voltage VDD), and then discharges the bit line BL by the NAND string 10 selected by the row decoder 2 to sense the discharge state of the bit line BL. That is, the sense amplifier 4 amplifies the voltage of the bit line BL and senses the data of the memory cell MC. Then, the read data is transferred to the external device via the data line Dline. At this time, the bit lines BL not to be read are fixed at the voltage VDD.

During the data writing, the sense amplifier 4 transfers the write data to the bit line BL to be written. Specifically, when the “1” data is to be written, the predetermined voltage (such as the voltage VDD) is transferred to the bit line BL, and when the “0” data is to be written, for example, VSS(=0V) or a voltage V1 (>VSS) is transferred to the bit line BL according to the belonging group. At this time, the bit lines BL not to be read are fixed at the voltage VDD.

<ECC Circuit 5>

The ECC circuit 5 is directed for correcting an error of data, and calculates a rate of occurrence of error reading per data held by the read page. The rate of occurrence is a rate of the number of corrected bits relative to the total number of bits in the memory cells in the page direction, for example.

<Voltage Generator 6>

The voltage generator 6 comprises a first voltage generator 61 to a fourth voltage generator 64. The first voltage generator 61 to a fifth voltage generator 65 will be described with reference to FIG. 3.

As shown in FIG. 3, the first voltage generator 61 to the fourth voltage generator 64 comprise a limiter 6b and a charge pump circuit 6a. The charge pump 6a generates voltages needed for the data write operation and read operation, for example, in response to an instruction from the controller 7. Each of the generated voltages is output from a node N1 to, for example, the row decoder 2 in the NAND flash memory.

The limiter 6b controls the charge pump circuit 6a depending on a potential of the node N1 while monitoring the potential of the node N1. That is, when the potential of the node N1 is higher than a predetermined value, the limiter 6b stops the pumping of the charge pump circuit 6a and lowers the potential of the node N1. Then, when the potential of the node N1 is lower than the predetermined value, the limiter 6b instructs the charge pump circuit 6a to perform pumping, and increases the potential of the node N1.

The voltages generated by the first voltage generator 61 and the second voltage generator 62 will be described below. The first voltage generator 61 generates a voltage VPGM1 to a voltage VPGM4 as the data write voltages, and transfers the write voltages to the selected word lines WL. The voltages VPGM1 to VPGM4 are as high as the charges of the channels in the memory cells MC are injected in the charge accumulation layer and the threshold of the memory cells MC transits to another level, and the relationship of voltage VPGM4>voltage VPGM3>voltage VPGM2>voltage VPGM1 is established. When the voltage VPGM1 to the voltage VPGM4 are not discriminated, they will be simply called voltage VPGM below.

The second voltage generator 62 generates a voltage VPASS and transfers the voltage VPASS to the non-selected word lines WL. The voltage VPASS is a voltage at which the memory cells MC are turned ON irrespective of the held data.

The third voltage generator 63 generates a voltage VCGR and transfers it to the selected word lines WL. The voltage VCGR is dependent on data to be read. In the present embodiment, the voltage VCGR may function as the verify voltage. That is, when the voltage VCGR functions as the verify voltage, the value of the voltage VCGR changes depending on the number of times of writing and is positioned at the center of the distributed thresholds of the memory cells MC. That is, the voltage VCGR is positioned at the center of the distribution of thresholds of the memory cells MC increasing depending on the number of times of writing. For example, it is assumed that the distribution of thresholds of the memory cells MC transits four times from the erase state by the write operation. In this case, each verify level is a median value of a respective distribution of thresholds transiting four times. This will be assumed as voltage VCGR1, voltage VCGR2, voltage VCGR3 and voltage VCGR4 below, respectively.

The fourth voltage generator 64 generates a voltage VREAD and transfers the voltage VREAD to the non-selected word lines WL during the data reading. The voltage VREAD is a voltage at which the memory cells MC are turned ON irrespective of the held data.

<Controller 7>

The controller 7 holds frequency data 71. The frequency data 71 holds a count value indicating how many times the write operation has been performed on the memory cells MC. The controller 7 refers to the value of the frequency data 71 and controls the third voltage generator 63. That is, the controller 7 refers to the number of times of the write operation performed on the memory cells MC during the write verifying, and controls the voltage VCGR generated by the third voltage generator 63 such that the verify voltage is near the center of the distribution of thresholds which may be dependent on the number of times of the write operation.

Further, the controller 7 terminates the write operation when the frequency data 71 reaches a predefined value. If the number of memory cells MC having a threshold voltage higher than the verify level does not reach half the total number when the target frequency data 71 of the memory cells MC reaches the predefined value, the write operation may be performed until the number of memory cells MC having a threshold voltage higher than the verify level reaches half the total number.

The controller 7 controls the voltage to be transferred to the bit lines BL during a next write operation depending on whether the threshold voltage of the memory cells MC is higher than the verify level, as a result of the write verifying. That is, when the threshold voltage is in the first group lower than the verify level, for example, the voltage VSS is transferred to the bit lines BL to which the memory cells MC are connected, and when the threshold voltage is in the second group higher than the verify level, the voltage V1 (>0) is transferred to the bit lines BL connected to the memory cells MC. The voltage transferred to the bit lines BL is controlled by the sense amplifier 4.

The controller 7 controls the total operations of the NAND flash memory. That is, the operation sequence in the data write operation, read operation and erase operation is performed based on the address and the command given from the external device. The controller 7 generates a block select signal/column select signal based on the address and the operation sequence. The controller 7 outputs the block select signal to the row decoder 2.

<Write Operation>

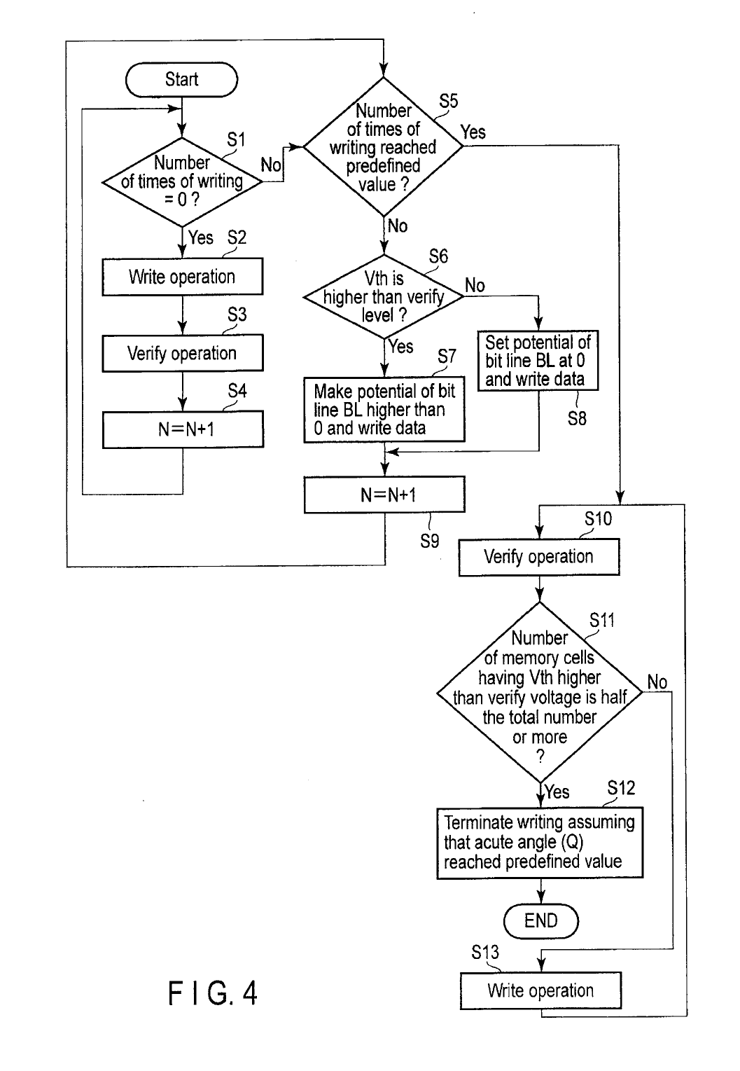

The write operation in the NAND flash memory will be described below with reference to FIG. 4. FIG. 4 is a flowchart showing the write operation. Herein, the write operation is based on the “0” data writing in FIG. 2.

The controller 7 first refers to the frequency data 71 and confirms the number of times of writing N into the memory cells MC. Consequently, in the case of the number of times of writing N=0 (YES in S1), the write operation and the write verify operation are performed on the memory cells MC Lo be written (S2, S3). That is, assuming that the potential of the bit lines BL is a write-permitted potential (such as voltage VSS (=0V)), the voltage generator 6 transfers the voltage VPGM to the selected word lines WL and the voltage VPASS to the non-selected word lines WL for the data writing.

Then, the potential of the bit lines BL is assumed as VDD[V], the verify voltage is transferred as the voltage VCGR to the selected word lines WL, and the voltage VREAD is transferred to the non-selected word lines WL for the write verifying. Then, the controller 7 increments the number of times of writing N by “+1” (S4).

In the case of the number of times of writing N≠0 (NO in S1), the controller 7 confirms whether the number of times of writing N has reached the predefined value. Consequently, when the number of times of writing N has not reached the predefined value (NO in S5), the controller 7 further confirms whether the distribution of thresholds of the memory cells MC is higher than the verify level, that is, confirms which group the distribution belongs to, and then performs a further write operation and write verify operation. When the distribution of thresholds of the memory cells MC after the writing is higher than the verify level, that is, when the distribution belongs to the second group, the controller 7 causes the second buffer 32 to store the “0” data, for example, and when the distribution is lower than the verify level, that is, when the distribution belongs to the first group, the controller 7 causes the second buffer 32 to store the “1” data, for example.

When the stored data in the second buffer 32 is “0”, that is, when the threshold voltage of the memory cells MC is higher than the verify level (YES in S6), the potential of the bit lines BL is assumed as the write-permitted potential (higher than the voltage VSS) and the voltage generator 6 transfers the voltage VPGM to the selected word lines WL and the voltage VPASS to the non-selected word lines WL (S7).

When the stored data in the second buffer 32 is “1”, that is, when the threshold voltage of the memory cells MC is lower than the verify level (NO in S6), the potential of the bit lines BL is assumed as the write-permitted potential (the voltage VSS (0V)), and the voltage generator 6 transfers the voltage VPGM to the selected word lines WL and the voltage VPASS to the non-selected word lines WL (S8). Thereafter, the number of times of writing N is incremented by “+1” (S9).

As a result of step S9, when the value of the number of times of writing N reaches the predefined value (YES in S5), the controller 7 performs the write verify operation on the memory cells MC to be written (S10). As a result of step S10, when the number of memory cells MC having a threshold voltage exceeding the verify level is more than half the total number (YES in S11), the controller 7 determines that an acute angle (Q) of the distribution of thresholds of the memory cells MC is narrower than a predefined value, and terminates the write operation (S12). To the contrary, when the number of memory cells MC having a threshold voltage exceeding the verify level does not reach half the total number (NO in S11), the controller 7 determines that the acute angle (Q) of the distribution of thresholds of the memory cells MC is wider than the predefined value, that is, that the distribution of thresholds is not sufficiently narrowed (NO in S11), performs a further write operation (S13), and returns to the processing in step S10.

<Conceptual Diagram of Write Operation>

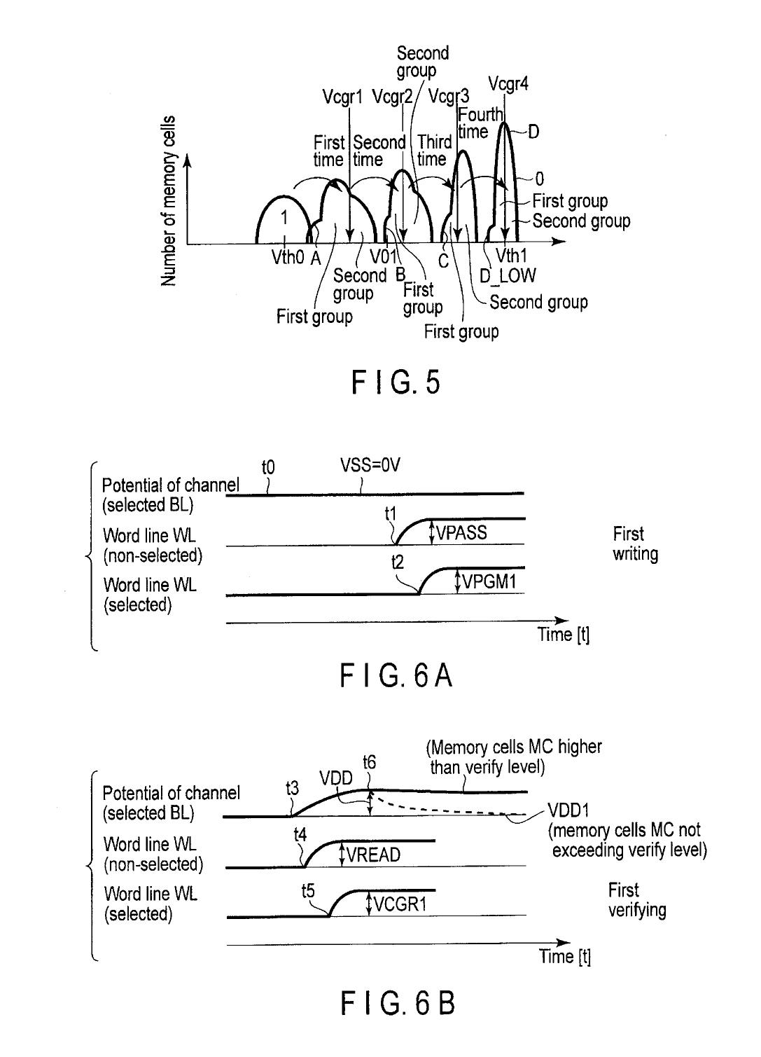

There will be described below the write operation and the verify operation when the predefined value of the number of times of writing N is set at “4”, as well as the distribution of thresholds of the memory cells MC varying depending on the write operation with reference to FIG. 5.

As shown in FIG. 5, the distribution of thresholds of the memory cells MC first transits to a distribution of thresholds in state A from the erase state (the distribution of thresholds holding the “1” data in the Figure) by the first write operation. That is, in the case of the number of times of writing N=0 (S1), the controller 7 transfers the write-permitted voltage (the voltage VSS (0V)) to the bit lines BL, and then transfers the voltage VPGM to the selected word lines WL and the voltage VPASS to the non-selected word lines WL, thereby performing the data writing.

Then, the write verifying is performed after the write operation (S3). That is, the controller 7 causes the third voltage generator 63 to generate the voltage VCGR1 as the verify voltage corresponding to the number of times of writing N=1 and to transfer the voltage to the memory cells MC to be written. The voltage VREAD is transferred to the non-selected word lines WL. At this time, the bit lines BL are previously precharged at the voltage VDD.

As a result of the write verifying, when the distribution of thresholds of the memory cells MC is lower than the voltage VCGR1 (NO in S6), the controller 7 sets the potential of the bit lines BL at the voltage VSS during a next write operation (S8). When the distribution is higher than the voltage VCGR1 (YES in S6), the potential to be transferred to the bit lines BL is precharged at the voltage V1, for example, higher than the voltage VSS, thereby performing the data writing (S7). That is, the potential of the bit lines BL is set at zero potential for the memory cells MC whose property is not good and whose threshold voltage does not increase, and the amount of charges to be injected into the charge accumulation layer is reduced for the memory cells MC whose property is good and whose threshold voltage rapidly increases so that the distribution of thresholds of the memory cells MC is narrowed per write operation.

Until the predefined value is reached, that is, when the number of times of writing N=4 is reached, the controller 7 performs the write operation. As described above, the voltage VCGR1 to the voltage VCGR4 are at the median of the distribution of thresholds which the memory cells MC can take, respectively, and the relationship of voltage VCGR1<voltage VCGR2<voltage VCGR3<voltage VCGR4 is established.

When the number of times of writing N reaches the predefined value of “4”, the controller 7 determines that the distribution of thresholds of the memory cells MC is in state D, and terminates the write operation. When the number of times of writing N reaches the predefined value of “4”, the controller 7 may terminate the write operation based on the information on that the distribution of thresholds exceeds the voltage VCGR4 and on whether the number of memory cells MC having the distribution of thresholds higher than the voltage VCGR4 is more than half the total number. That is, when the number of memory cells MC which are in the

OFF state at the voltage VCGR4 during the write verifying, that is, which have a threshold voltage higher than the voltage VCGR4 is more than half the total number, the controller 7 determines that the acute angle (Q) of the distribution of thresholds of the memory cells MC would be narrow, and terminates the data write operation (S12). At this time, the lower potential (denoted as D_Low in FIG. 5) in the distribution of thresholds of the memory cells MC transited to state D is not checked, but the acute angle (Q) is sufficiently narrow for the lower potential and the memory cells MC positioned at the lower potential are determined as error-correctable in the ECC circuit 5. “More than half the total number” described above indicates half the total memory cells assuming that the number of memory cells MC connected to the selected word lines WL to be written is the total number in units of page.

<Operation of Each Signal Line>

<Number of Times of Writing N=0>

There will be described below a change in potential of each signal line (word line WL, bit line BL) in the write operation (“0” data writing) with reference to FIGS. 6A and 6B. FIGS. 6A and 6B are time charts showing the changes in potential of the selected bit lines BL, the selected word lines WL and the non-selected word lines WL during the first write operation and write verify operation.

As shown in FIG. 6A, in the case of the number of times of writing N=0, that is, when the memory cells MC are in the erase state, the sense amplifier 4 sets the potential of the bit lines BL at the voltage VSS after time t0. Then, the first voltage generator 61 and the second voltage generator 62 transfer the voltage VPGM and the voltage VPASS to the selected word lines WL and the non-selected word lines WL at times t2 and t3, respectively. Thereby, the distribution of thresholds of the memory cells MC transits to state B in FIG. 5.

Then, the controller 7 performs the write verifying on the memory cells MC transited to state B. That is, while the sense amplifier 4 precharges the potential of the channels at the voltage VDD, for example, at time t3 as shown in FIG. 6B, the fourth voltage generator 64 transfers the voltage VREAD to the non-selected word lines WL at time t4 and the third voltage generator 63 transfers the voltage VCGR1 as the verify voltage to the selected word lines WL at time t5. As described above, when the distribution of thresholds of the memory cells MC is lower than the voltage VCGR1, the memory cells MC are turned ON after time t6 and the potential of the channels transits from the voltage VDD to the voltage VSS. To the contrary, when the distribution of thresholds of the memory cells MC is higher than the voltage VCGR1, the memory cells MC are turned OFF even after time t6 and the potential of the channels maintains almost at the voltage VDD.

<Number of Times of Writing N=1>

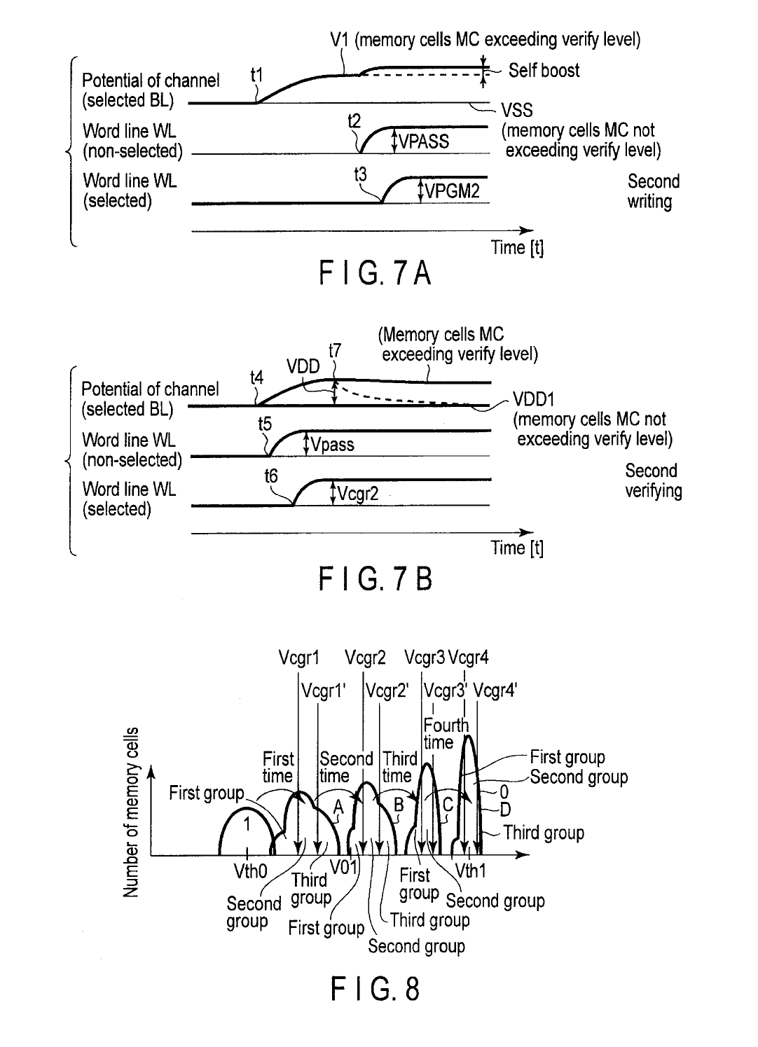

There will be described below a change in potential of each signal line (word line WL, bit line BL) during the write operation (“0” data writing) with reference to FIGS. 7A and 7B. FIGS. 7A and 7B are time charts showing the changes in potential of the selected bit lines BL, the selected word lines WL and the non-selected word lines WL during the second write operation and write verify operation. That is, the distribution of thresholds of the memory cells MC is transited from state B to state C in FIG. 5 by the write operation. An explanation of the same writing and write verifying as those at the number of times of writing N=1 will be omitted.

As shown in FIG. 7A, when the threshold voltage of the memory cells MC is higher than the voltage VCGR1, the potential of the bit lines BL is precharged from the voltage VSS to the voltage V1, for example, at time t1 by the write verify operation. To the contrary, when the threshold voltage of the memory cells MC is lower than the voltage VCGR, the potential of the bit lines BL is kept at the voltage VSS after time t1.

Then, the voltage VPASS is transferred to the non-selected word lines WL at Lime t2 and the voltage VPGM2 (>the voltage VPGM1) is transferred to the selected word lines WL at time t3. Thereby, the distribution of thresholds is transited from state B to state C in FIG. 5. As described above, the width of the distribution of thresholds which the memory cells MC can take is narrower than that in state B due to the second writing.

Then, the controller 7 performs the second write verifying. That is, as described above, the controller 7 refers to the frequency data 71 to cause the third voltage generator 63 to generate the verify voltage corresponding to the value of the data, thereby performing the read operation. Specifically, the potential of the bit lines BL to which the memory cells MC to be read are connected is increased from the voltage VSS to the voltage VDD, for example, at time t4. Then, the voltage VPASS is transferred to the non-selected word lines WL and the voltage VCGR2 is transferred to the selected word lines WL.

As described above, as a result of the write verifying, when the distribution of thresholds of the memory cells MC is lower than the voltage VCGR2, the memory cells MC are turned ON after time t7 and the potential of the channels transits from the voltage VDD to the voltage VSS. To the contrary, when the distribution of thresholds of the memory cells MC is higher than the voltage VCGR2, the memory cells MC are turned OFF even after time t7 and the potential of the channels maintains almost at the voltage VDD.

The explanation has been made herein assuming that the value of the frequency data 71 takes N=0, 1, but the same operations are performed also when the number of times of writing is more.

With the semiconductor memory device according to the present embodiment, a rapid write processing can be realized while the distribution of thresholds of the memory cells MC is narrowed. That is, with the semiconductor memory device according to the present embodiment, the controller 7 comprises the frequency data 71, and further comprises a plurality of buffers capable of holding the halved distributions of thresholds of the memory cells MC.

In other words, with the semiconductor memory device according to the present embodiment, as a result of each writing, the median value of the transited distribution of thresholds of the memory cells MC is assumed as the write verify voltage. That is, as described above, the potential of the bit lines BL is assumed as the voltage VSS at a next write operation and the threshold voltage is promoted to increase for the memory cells MC having the threshold voltage lower than the voltage VCGR corresponding to the number of times of writing N. To the contrary, the potential of the bit lines BL is made higher than the voltage VSS at a next write operation and the threshold voltage is restricted from increasing for the memory cells MC having the threshold voltage higher than the voltage VCGR. Thereby, the width of the distribution of thresholds of the memory cells MC can be narrowed per write operation.

The controller 7 refers to the number of times of continuous writing N into the memory cells MC, thereby grasping the write operation end timing. That is, when the number of times of writing N reaches a predetermined predefined value, it is possible to grasp that the distribution of thresholds of the memory cells MC has transited to the target distribution. The predefined value is different per property of the memory cells MC, but the frequency data 71 according to the present embodiment holds a different predefined value per property of the memory cells MC. Thus, the controller 7 uses the method for verifying the lower potential of the memory cells MC thereby to rapidly terminate the writing even when the write verify and write operations are not repeated.

Further, the controller 7 can grasp the number of memory cells MC higher or lower than the write verify voltage. This is because the distribution of thresholds of the memory cells MC commonly connected to a certain word line WL is read at the median value of the distribution of thresholds, and the second buffer 32 holds the result indicating whether the distribution is higher or lower than the median value. That is, even when the number of times of writing N reaches the predefined value, if the number of memory cells MC having the distribution of thresholds higher than the write verify voltage is equal to or less than half the total number for the memory cells MC commonly connected to a word line WL, the write operation is further performed. That is, when the controller 7 grasps the acute angle (Q) of the distribution of thresholds based on the number of memory cells MC exceeding the write verify voltage and the number of memory cells MC exceeding the write verify voltage reaches half the total number, the controller 7 determines that the acute angle (Q) has reached the predefined value or less. From the above, rapid data writing can be performed while the width of the distribution of thresholds of the memory cells MC is narrowed.

When the distribution of thresholds of the memory cells MC reaches the target level, the semiconductor memory device according to the present embodiment does not confirm where the lower potential of the distribution of thresholds is positioned, but assumes the number of memory cells MC at the lower potential as being in a relievable range by the ECC circuit 5 based on the above acute angle (Q).

### Second Embodiment

A semiconductor memory device according to a second embodiment will be described below. For the semiconductor memory device according to the present embodiment, two verify levels are provided for the distribution of thresholds of the memory cells MC. An explanation of similar structure to that of the first embodiment will be omitted below.

<Third Buffer 33>

The present embodiment assumes that a third buffer 33 can hold data as to where a threshold voltage of the memory cells MC is positioned relative to the two verify levels. In the present embodiment, two verify levels are arranged for a distribution of thresholds. Specifically, the first verify level and the second verify level (>the first verify level) are arranged from below for the distribution of thresholds. In this case, it is assumed that the memory cells MC having a threshold voltage lower than the first verify level are in the first group, the memory cells MC having a threshold voltage higher than the first verify level and lower than the second verify level are in the second group, and the memory cells MC having a threshold voltage higher than the second verify level are in the third group. The third buffer 33 can hold data as to which of the first to third groups the memory cells MC belong to.

<Sense Amplifier 4>

A sense amplifier 4 according to the present embodiment transfers a voltage VSS, a voltage V1 and a voltage V2 to bit lines BL during a next write operation depending on the position of the threshold voltage determined by the write verifying.

<Third Voltage Generator 63>

A third voltage generator 63 according to the present embodiment generates the voltage VCGR1 to the voltage VCGR4 as the verify voltages, and additionally generates a voltage VCGR1′, a voltage VCGR2′, a voltage VCGR3′ and a voltage VCGR4′. Herein, it is assumed that the relationships of voltage VCGR1′>voltage VCGR1, voltage VCGR2′>voltage VCGR2, voltage VCGR3′>VCGR3, and voltage VCGR4′>voltage VCGR4 are established.

Under the above conditions, the memory cells MC having a threshold voltage lower than the voltage VCGR1, the voltage VCGR2, the voltage VCGR3 and the voltage VCGR4 in respective states A to D are assumed as being in the first group. The memory cells MC having a threshold voltage higher than the voltage VCGR1, the voltage VCGR2, the voltage VCGR3 and the voltage VCGR4 and lower than the voltage VCGR1′, the voltage VCGR2′, the voltage VCGR3′ and the voltage VCGR4′ in the respective states A to D are assumed as being in the second group. Further, the memory cells MC having a threshold voltage higher than the voltage VCGR1′, the voltage VCGR2′, the voltage VCGR3′ and the voltage VCGR4′ in the respective states A to D are assumed as being in the third group.

<Write Operation>

A write operation in the NAND flash memory will be described below with reference to FIG. 8. There will be described the write operation and the verify operation when a predefined value of the number of times of writing N is assumed at “4”, as well as the distribution of thresholds of the memory cells MC varying depending on the write operation similarly to the first embodiment. An explanation of similar operations to those in the first embodiment will be omitted.

As shown in FIG. 8, the distribution of thresholds of the memory cells first transits from an erase state to the distribution of thresholds in state A by the first write operation. The write verifying is then performed. That is, a controller 7 causes the third voltage generator 63 to generate the voltage VCGR1 and the voltage VCGR1′ as the verify voltages corresponding to the number of times of writing N=1 and to sequentially transfer the same to the memory cells MC to be written.

As a result of the write verifying, when the distribution of thresholds of the memory cells MC is lower than the voltage VCGR1, the memory cells MC are determined as being in the first group, and the controller 7 performs the write operation assuming the potential of the bit lines BL at the voltage VSS during a next write operation. When the threshold voltage of the memory cells MC is higher than the voltage VCGR1 and lower than the voltage VCGR1′, the controller 7 determines that the memory cells MC are in the second group, and precharges the potential to be transferred to the bit lines BL during the next write operation at the voltage V1 higher than the voltage VSS, for example, and performs the data writing. Further, when the threshold voltage of the memory cells MC is higher than the voltage VCGR1′, the controller 7 determines that the memory cells MC are in the third group, and precharges the potential to be transferred to the bit lines BL during the next write operation at the voltage V2 higher than the voltage V1, for example, and performs the data writing. Also in the present embodiment, the controller 7 performs the write operation until the predefined value is reached, that is, until the number of times of writing N=4 is reached.

With the semiconductor memory device according to the present embodiment, the threshold voltage of the memory cells MC can be further narrowed. This is because the two verify levels are set for the write verifying performed after the write operation unlike the first embodiment.

That is, in the semiconductor memory device according to the present embodiment, the threshold voltages of the memory cells MC are discriminated among the first to third groups based on the two verify levels. Thereby, for example, the potential of the bit lines BL is set at the voltage VSS and the amount of charges to be injected into a charge accumulation layer is increased for the memory cells MC having a lower threshold voltage. To the contrary, the voltage V1 and the voltage V2 with a difference therebetween are transferred to the bit lines BL during the writing for the memory cells MC belonging to the second and third groups, thereby restricting the threshold voltages from increasing. Thereby, the threshold voltage of the memory cells MC belonging to the first group further increases and approaches the threshold voltages of the second and third groups. To the contrary, the threshold voltages of the memory cells MC belonging to the second and third groups are restricted from increasing.

Therefore, the width of the distribution of thresholds of the memory cells MC is narrowed per write operation. This is because in the semiconductor memory device according to the present embodiment, the groups of the memory cells MC are divided into the first to third groups thereby to transfer the finer voltages to the bit lines BL.

There has been described the case that the memory cells MC hold the two-level data in the first and second embodiments, but the memory cells MC may hold four- or more-level data. In this case, the third voltage generator 63 generates a verify level corresponding to the four-level data. One or two verify levels may be generated for a respective distribution of thresholds similarly in the first and second embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a memory cell array in which memory cells capable of holding two- or more-level data are formed along rows and columns;
a voltage generator generating a write voltage and a verify voltage depending on the number of times of writing, transferring a first voltage as the write voltage to the memory cell having a threshold voltage lower than the verify voltage depending on the number of times of writing, and transferring a second voltage lower than the first voltage as the write voltage to the memory cell having a threshold voltage higher than the verify voltage;
a controller causing the voltage generator to transfer the verify voltage to the memory cell and to terminate a write operation when the number of memory cells having a threshold exceeding a predetermined voltage reaches half the total number,
wherein the controller performs the writing at least twice.

2. The device according to claim 1, further comprising:
a buffer holding a result obtained by a verify operation for verifying a distribution of thresholds of the memory cells,
wherein the controller causes the voltage generator to generate either the first voltage or the second voltage as a voltage to be transferred to the memory cell during a next write operation depending on data stored in the buffer.

3. The device according to claim 2, further comprising:
a bit line connected to a drain of the memory cell,
wherein the first voltage and the second voltage are each a difference in potential between a control gate of the memory cell and the bit line.

4. The device according to claim 3, wherein
the voltage generator generates a third voltage and a fourth voltage lower than the third voltage,
the voltage generator transfers the third voltage to the bit line connected to the memory cell having the threshold voltage higher than the verify voltage, and
transfers the fourth voltage to the bit line connected to the memory cell having the threshold voltage lower than the voltage.

5. The device according to claim 4, wherein
the voltage generator generates a fifth voltage and a sixth voltage higher than the fifth voltage as the verify voltages and a seventh voltage and an eighth voltage higher than the seventh voltage as the write voltages depending on the threshold voltage of the memory cell per writing.

6. The device according to claim 5, wherein
the voltage generator transfers a ninth voltage to the bit line connected to the memory cell having the threshold voltage lower than the fifth voltage,
transfers a tenth voltage higher than the ninth voltage to the bit line connected to the memory cell having the threshold voltage higher than the fifth voltage and lower than the sixth voltage, and
transfers an eleventh voltage higher than the tenth voltage to the bit line connected to the memory cell having the threshold voltage higher than the sixth voltage.

7. The device according to claim 1, wherein
when the number of times of writing reaches a predefined value, the controller determines whether the number of memory cells exceeding the threshold reaches half the total number, and
terminates the write operation when the number of memory cells reaches half the total number.

8. A semiconductor memory device comprising:
a memory cell array in which memory cells capable of holding two- or more-level data are formed along rows and columns;
a voltage generator generating a write voltage and a verify voltage depending on the number of times of writing, transferring a first voltage as the write voltage in a memory cell having a threshold voltage lower than the verify voltage depending on the number of times of writing, and transferring a second voltage lower than the first voltage as the write voltage to the memory cell having a threshold voltage higher than the verify voltage; and
a controller comprising a counter by which the number of times of writing is counted, causing the voltage generator to generate the write voltage and the verify voltage depending on the value of the counter,
wherein the controller performs the writing at least twice.

9. The device according to claim 8, wherein
when the value of the counter reaches a predefined value, the controller determines whether the number of memory cells having a threshold exceeding a predetermined voltage reaches half the total number.

10. The device according to claim 9, wherein
as a result of the determination, when the number of memory cells is half the total number or more, the controller terminates the writing.

11. The device according to claim 9, wherein
as a result of the determination, when the number of memory cells is half the total number or less, the controller performs the writing until the number of memory cell having the threshold exceeding the predetermined voltage reaches half the total number or more.

12. The device according to claim 9, further comprising:
a first buffer holding a result obtained by a verify operation for verifying a distribution of thresholds of the memory cells,
wherein the controller causes the voltage generator to generate either the first voltage or the second voltage as a voltage to be transferred to the memory cell during a next write operation depending on data stored in the first buffer.

13. The device according to claim 9, further comprising:
a bit line connected to a drain of the memory cell,
wherein the first voltage and the second voltage are each a difference in potential between a control gate of the memory cell and the bit line.

14. The device according to claim 9, wherein
the voltage generator generates a third voltage, and
the voltage generator transfers the third voltage to the bit line connected to the memory cell irrespective of the magnitude of the threshold voltage relative to the verify voltage.

15. The device according to claim 9, further comprising:
a second buffer holding a result obtained by a verify operation for verifying a distribution of thresholds of the memory cells,
wherein the voltage generator generates a fourth voltage and a fifth voltage higher than the fourth voltage as the verify voltages depending on the threshold voltage of the memory cell per writing, and
the second buffer holds data as to whether the threshold voltage of the memory cell is lower than the fourth voltage, equal to or higher than the fourth voltage and lower than the fifth voltage, or equal to or higher than the fifth voltage as a result of the verify operation.

16. A method for controlling a semiconductor memory device, the method being performed by a controller, comprising:
confirming a count value of a counter indicating the number of times of writing in a memory cell;
when the count value is zero, applying a write voltage to the memory cell while assuming a bit line at a zero potential;
applying a verify voltage to the memory cell in order to confirm whether a threshold voltage of the memory cell is higher or lower than a predetermined voltage;
incrementing the count value of the counter by +1 and confirming whether the count value reaches a predefined value; and
confirming whether the number of memory cells having a threshold exceeding a predetermined voltage reaches half the total number depending on whether the count value reaches the predefined value.

17. The method according to claim 16, further comprising:
when the count value reaches the predefined value and the number of memory cells exceeding the predetermined voltage reaches half the total number, the controller determining that an acute angle reaches a predefined value and terminating the writing into the memory cell.

18. The method according to claim 16, further comprising:
when the count value does not reach the predefined value, the controller confirming whether the threshold voltage of the memory cell is higher or lower than the verify voltage;
when the threshold voltage is lower than the verify voltage, the controller applying a zero potential to the bit line and performing writing again;
when the threshold voltage is higher than the verify voltage, the controller applying a potential higher than the zero potential to the bit line and performing the writing again; and
after the writing, the controller incrementing the count value by +1 and confirming whether the count value reaches the predefined value.

19. The method according to claim 18, further comprising:
assuming a first voltage and a second voltage higher than the first voltage as the verify voltages relative to the threshold voltage of the memory cell; and
a buffer holding data as to whether a threshold voltage of the memory cell is lower than the first voltage or less, higher than the first voltage and equal to or less than the second voltage, or higher than the second voltage.
